(19) United States
(12) Patent Application Publication
(10) Pub. No.: US 2018/0067582 A1
(43) Pub. Date: Mar. 8, 2018

(54) IN-CELL TOUCH PANEL AND DISPLAY DEVICE

(71) Applicants: BOE TECHNOLOGY GROUP CO., LTD., Beijing (CN); BEIJING BOE DISPLAY TECHNOLOGY CO., LTD., Beijing (CN)

(72) Inventor: Baoqiang WANG, Beijing (CN)

(21) Appl. No.: 15/561,593

(22) PCT Filed: Apr. 15, 2016
(86) PCT No.: PCT/CN2016/079444

§ 371 Date: Sep. 26, 2017

(30) Foreign Application Priority Data
Jun. 18, 2015 (CN) 201510342189.7

(51) Int. Cl. G06F 3/044; H03K 17/96

(52) U.S. Cl. CPC G06F 3/044; G02F 1/13338; H03K 17/962

(57) ABSTRACT

An in-cell touch panel and a display device are disclosed. In the in-cell touch panel, the data line is multiplexed as a connection line for electrically connecting the self-capacitance electrode to the touch detection chip. During a display period, the first control component is used to control each self-capacitance electrode to be disconnected from a corresponding connection line, and the second control component is used to control each data line to be electrically connected to the data driving circuit. During a touch period, the first control component is used to control each self-capacitance electrode to be connected to a corresponding connection line, and the second control component is used to control the data lines multiplexed as the connection lines to be electrically connected to the touch detection chip.

### RELATED APPLICATION

The present application is the U.S. national phase entry of PCT/CN2016/079444, with an international filling date of Apr. 15, 2016, which claims the benefit of Chinese Patent Application NO. 201510342189.7, filed on Jun. 18, 2015, the entire disclosure of which is incorporated herein by reference.

### FIELD OF THE INVENTION

The present disclosure relates to the field of display technology, and particularly to an in-cell touch panel and a display device.

### BACKGROUND

Touch panels can be classified as Add-on-Mode touch panel, On-Cell touch panel and In-Cell touch panel in terms of the constituent structure. For the in-cell touch panel, the touch electrode is embedded inside the liquid crystal display screen, which can decrease the overall thickness of the display module and reduce the manufacturing cost of the touch panel.

The existing in-cell touch panel generally detects a touch position based on the theory of mutual capacitance or self capacitance. As compared to a mutual-capacitance touch panel, the signal-to-noise ratio of touch for a self-capacitance touch panel is relatively high, and the accuracy of touch sensing is higher.

In the existing self-capacitance touch panel, as shown in FIG. 1, there are a plurality of self-capacitance electrodes 101 disposed in the same layer and insulated from each other, each of which is electrically connected to a connection line 103 additionally disposed through a via hole 102. Each of the connection lines 103 is electrically connected to a touch detection chip 104. The connection line 103 is disposed in the light shielding area where a data line 105 resides, and the data line 105 is electrically connected to a data driving circuit 106. When the human body does not touch the panel, the capacitance for each of the self-capacitance electrodes is a fixed value. When the human body touches the panel, the capacitance for the corresponding self-capacitance electrode is the fixed value plus the body capacitance. The touch detection chip can determine the touch position by detecting a change in the capacitance value of each of the self-capacitance electrodes during the touch period.

In the above self-capacitance touch panel, the connection lines electrically connected to the self-capacitance electrodes are generally made of an opaque metal and need to be shielded by a black matrix to avoid interference with other light-transmitting areas of the touch panel. These connection lines would decrease the aperture ratio of the touch panel. Moreover, when the aperture ratio of the touch panel is relatively small, it is necessary to increase the intensity of the backlight in order to ensure the display brightness of the touch panel, which would increase the power consumption of the touch panel consequently.

Therefore, how to increase the aperture ratio of the self-capacitance touch panel so as to reduce the power consumption of the touch panel accordingly is a technical problem that needs to be solved by those skilled in the art.

### SUMMARY

In view of this, embodiments of the present disclosure provide an in-cell touch panel and a display device for increasing the aperture ratio of the self-capacitance touch panel so as to reduce the power consumption of the touch panel accordingly.

Therefore, an embodiment of the present disclosure provides an in-cell touch panel, comprising: a substrate, a gate line and a data line on the substrate, which are arranged in an intersecting and insulating manner, a plurality of self-capacitance electrodes on the substrate, which are insulated from the gate line and the data line and arranged in a matrix, and a touch detection chip for determining a touch position by detecting a change in a capacitance value of each self-capacitance electrode during a touch period. Each column of self-capacitance electrodes overlaps a plurality of data lines, the number of self-capacitance electrodes included in each column of self-capacitance electrodes is smaller than or equal to the number of data lines with which this column of self-capacitance electrodes overlap. The data line is multiplexed as a connection line for electrically connecting the self-capacitance electrode to the touch detection chip, each self-capacitance electrode is corresponding to one connection line. The touch panel further comprises a first control component and a second control component, the first control component being used for controlling each of the self-capacitance electrodes to be disconnected to from a corresponding connection line during a display period, and controlling each of the self-capacitance electrodes to be electrically connected to a corresponding connection line during the touch period, the second control component being used for controlling each data line to be electrically connected to a data driving circuit during the display period, and controlling the data line multiplexed as the connection line to be electrically connected to the touch detection chip during the touch period.

In a possible embodiment, the first control component comprises: a plurality of first thin film transistors which are insulated from the gate lines and in one-to-one correspondence with the self-capacitance electrodes, a plurality of first control lines which are insulated from the gate lines and the data lines and in one-to-one correspondence with respective rows of self-capacitance electrodes, and a first control circuit electrically connected to each of the first control lines. A gate of each of the first thin film transistors to which each row of self-capacitance electrodes corresponds is electrically connected to a first control line to which this row of self-capacitance electrodes corresponds, a source of each of the first thin film transistors is electrically connected to a corresponding self-capacitance electrode, a drain of each of the first thin film transistors is electrically connected to a corresponding connection line.

In a possible embodiment, the second control component comprises: a plurality of second thin film transistors in one-to-one correspondence with the data lines multiplexed as the connection lines, a plurality of third thin film transistors in one-to-one correspondence with the data lines, a second control line electrically connected to the second thin film transistor, a second control circuit electrically connected to the second control line, a third control line electrically connected to the third thin film transistor, and a third control circuit electrically connected to the third control line. Each of the second thin film transistors is used for connecting or disconnecting corresponding data lines multiplexed as the connection lines with the touch detection chip, a gate of each of the second thin film transistors is electrically connected to the second control line, a source of each of the second thin film transistors is electrically connected to the touch detection chip, a drain of each of the second thin film transistors is electrically connected to a corresponding data line multiplexed as the connection line. Each of the third thin film transistors is used for connecting or disconnecting each data line with the data driving circuit, a gate of each of the third thin film transistors is electrically connected to the third control line, a source of each of the third thin film transistors is electrically connected to the data driving circuit, a drain of each of the third thin film transistors is electrically connected to a corresponding data line.

In a possible embodiment, the touch panel further comprises a plurality of pixel units located on the substrate and arranged in a matrix, the first control line is located at a gap between two adjacent rows of pixel units.

In a possible embodiment, the first control line is disposed in a same layer as the gate line.

In a possible embodiment, each of the pixel units comprises a fourth thin film transistor and a pixel electrode, the first thin film transistor is disposed in a same layer as the fourth thin film transistor.

In a possible embodiment, the second control line is disposed in a same layer as the gate line.

In a possible embodiment, the touch panel further comprises a plurality of pixel units located on the substrate and arranged in a matrix, each of the pixel units comprises a fourth thin film transistor and a pixel electrode, the second thin film transistor is disposed in a same layer as the fourth thin film transistor.

In a possible embodiment, the third control line is disposed in a same layer as the gate line.

In a possible embodiment, the touch panel further comprises a plurality of pixel units located on the substrate and arranged in a matrix, each of the pixel units comprises a fourth thin film transistor and a pixel electrode, the third thin film transistor is disposed in a same layer as the fourth thin film transistor.

In a possible embodiment, a type of the first thin film transistor is the same as that of the second thin film transistor, a type of the first thin film transistor is complementary to that of the third thin film transistor, wherein the first control circuit, the second control circuit, and the third control circuit are the same control circuit.

In a possible embodiment, the self-capacitance electrodes are formed by dividing a common electrode layer on the substrate.

Another embodiment of the disclosure provides a display device, which comprises the in-cell touch panel according to any one of above mentioned embodiments.

For the in-cell touch panel and the display device provided by embodiments of the present disclosure, the data line is multiplexed as a connection line for electrically connecting the self-capacitance electrode to the touch detection chip. During the display period, the first control component is used to control each of the self-capacitance electrodes to be disconnected from a corresponding connection line, and the second control component is used to control each of the data lines to be electrically connected to the data driving circuit. During the touch period, the first control component is used to control each of the self-capacitance electrodes to be connected to a corresponding connection line, and the second control component is used to control the data lines multiplexed as connection lines to be electrically connected to the touch detection chip. In this way, a self-capacitance touch can be realized without disposing connection lines individually in the light-shielding area where the data lines reside, which can thereby increase the aperture ratio of the self-capacitance touch panel. As a result, in the case of achieving the same brightness as the displayed image of the existing touch panel, the intensity of the backlight can be decreased, and the power consumption of the touch panel can be further reduced.

### BRIEF DESCRIPTION OF THE DRAWINGS

FIG. 1 is a schematic view of an existing self-capacitance touch panel,

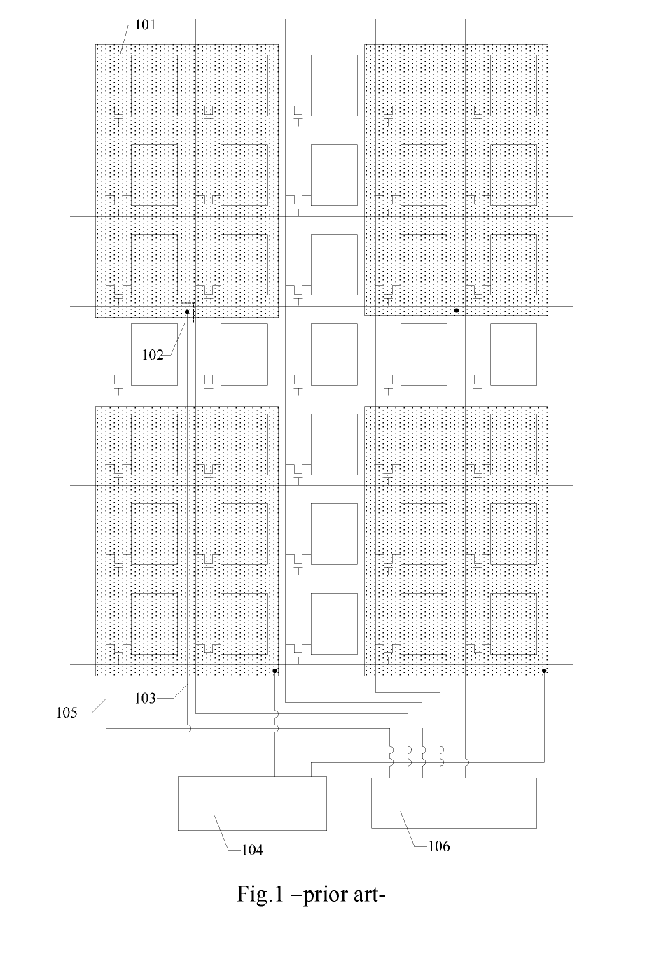

FIG. 2 is a schematic view of an in-cell touch panel provided by an embodiment of the present disclosure.

### DETAILED DESCRIPTION OF EMBODIMENTS

Examples of an in-cell touch panel and a display device provided by embodiments of the present disclosure will be described in detail below with reference to the accompanying drawings.

The shapes and dimensions of the components shown in the drawings do not reflect their true proportions, but are only intended to illustrate embodiments of the present disclosure.

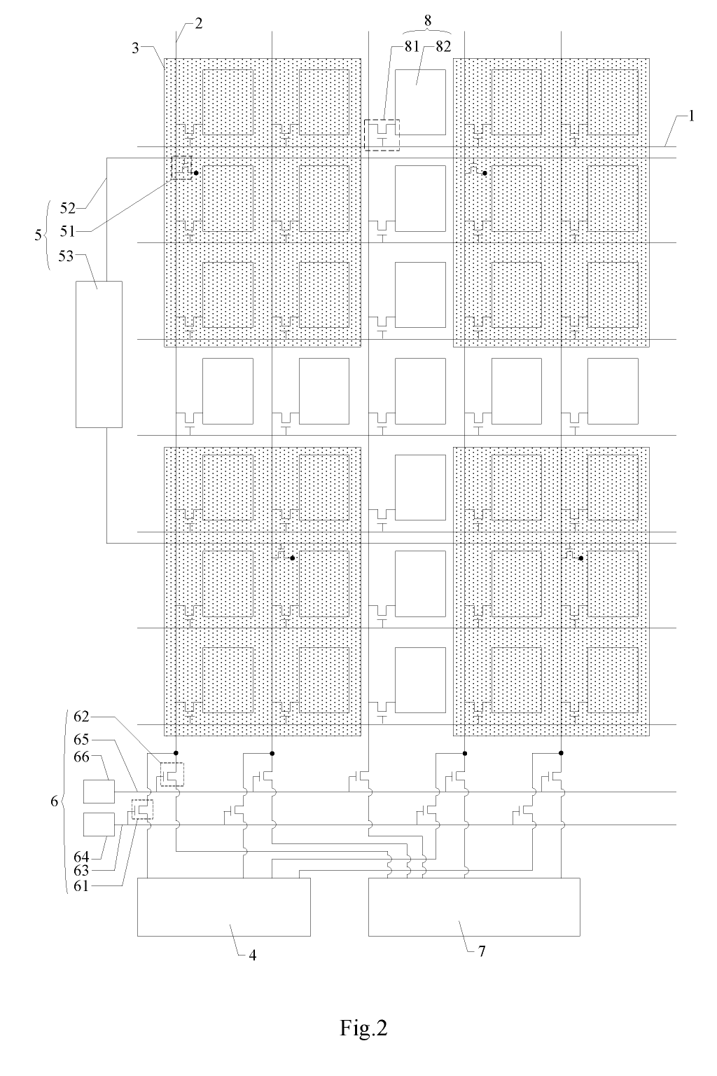

As shown in FIG. 2, an in-cell touch panel provided by an embodiment of the present disclosure may comprise: a substrate, a gate line 1 and a data line 2 located on the substrate, which are arranged in an intersecting and insulating manner, a plurality of self-capacitance electrodes 3 on the substrate, which are insulated from the gate lines 1 and the data lines 2 and arranged in a matrix, and a touch detection chip 4 for determining a touch position by detecting a change in the capacitance value of each of the self-capacitance electrodes 3 during the touch period.

Each column of self-capacitance electrodes 3 may overlap a plurality of data lines 2, and the number of self-capacitance electrodes 3 included in each column of self-capacitance electrodes 3 is smaller than or equal to the number of data lines 2 with which this column of self-capacitance electrodes overlaps. The data line 2 is multiplexed as a connection line for electrically connecting the self-capacitance electrode 3 to the touch detection chip 4, and each self-capacitance electrode 3 corresponds to one connection line.

The in-cell touch panel may further comprise a first control component 5 and a second control component 6. The first control component 5 is used for controlling the self-capacitance electrodes 3 to be disconnected from corresponding connection lines during the display period, and controlling the self-capacitance electrodes 3 to be electrically connected to corresponding connection lines during the touch period. The second control component 6 is to used for controlling the data lines 2 to be electrically connected to a data driving circuit 7 during the display period, and controlling the data lines 2 multiplexed as the connection lines to be electrically connected to the touch detection chip 4 during the touch period.

In the touch panel provided by the embodiment of the present disclosure, the data line is multiplexed as a connection line for electrically connecting the self-capacitance electrode to the touch detection chip. During the display period, the first control component is used to control each of the self-capacitance electrodes to be disconnected from a corresponding connection line, and the second control component is used to control each of the data lines to be electrically connected to the data driving circuit. During the touch period, the first control component is used to control the self-capacitance electrodes to be connected to corresponding connection lines, and the second control component is used to control the data lines multiplexed as connection lines to be electrically connected to the touch detection chip. In this way, a self-capacitance touch can be realized without disposing connection lines individually in the light-shielding area where the data lines reside, which can thereby increase the aperture ratio of the self-capacitance touch panel. As a result, in the case of achieving the same brightness as the displayed image of the existing touch panel, the intensity of the backlight can be decreased, and the power consumption of the touch panel can be further reduced.

The touch density of the touch panel may be on the millimeter scale. Upon implementation, the density of the self-capacitance electrodes and the area of each self-capacitance electrode can be selected based on the required touch density. However, the density of pixel electrodes is usually on the micron scale. Thus, one self-capacitance electrode may correspond to a plurality of pixel electrodes, and one column of self-capacitance electrodes may correspond to multiple columns of pixel electrodes. That is, one column of self-capacitance electrodes may overlap a plurality of data lines.

In the touch panel provided by the embodiment of the present disclosure, as shown in FIG. 2, the number of self-capacitance electrodes 3 included in each column of self-capacitance electrodes 3 may be equal to the number of data lines 2 with which this column of self-capacitance electrodes overlaps, and in this case, all the data lines may be multiplexed as the connection lines. Alternatively, in some embodiments, the number of self-capacitance electrodes included in each column of self-capacitance electrodes may be smaller than the number of data lines with which this column of self-capacitance electrodes overlaps, and at that time, part of the data lines may be multiplexed as connection lines. Moreover, in the case where the number of self-capacitance electrodes included in each column of self-capacitance electrodes is smaller than the number of data lines with which this column of self-capacitance electrodes overlaps, it is possible to only multiplex one data line as one connection line, or it is also possible to multiplex a plurality of data lines as one connection line.

In the touch panel provided by the embodiment of the present disclosure, as shown in FIG. 2, the first control component 5 may comprise a plurality of first thin film transistors 51 which are insulated from the gate lines 1 and in one-to-one correspondence with the respective self-capacitance electrodes 3, a plurality of first control lines 52 which are insulated from the gate lines 1 and the data lines 2 and in one-to-one correspondence with respective rows of self-capacitance electrodes 3, and a first control circuit 53 electrically connected to the respective first control lines 52. The gate of each of the first thin film transistors 51 to which each row of self-capacitance electrodes 3 corresponds is electrically connected to the first control line 52 to which this row of self-capacitance electrodes 3 corresponds, the source of each of the first thin film transistors 51 is electrically connected to a corresponding self-capacitance electrode 3 through a via hole (as denoted by the black dots shown in FIG. 2), and the drain of each of the first thin film transistors 51 is electrically connected to a connection line to which the corresponding self-capacitance electrode 3 corresponds.

In the touch panel provided by the embodiment of the present disclosure, although a first control line is added in the light-shielding area where the gate lines reside, and the first control line may also affect the aperture ratio of the touch panel, as compared to the case in which additional connection lines are disposed in the light-shielding area where the data lines reside, the first control line added in the light-shielding area where the gate lines reside has a smaller impact on the aperture ratio. Therefore, the touch panel provided by the embodiment of the present disclosure can increase the aperture ratio and reduce the power consumption of the touch panel accordingly, as compared to the existing touch panel.

Upon implementation, in the touch panel provided by the embodiment of the present disclosure, each of the first thin film transistors may be an N-type transistor, alternatively, each of the first thin film transistors may be a P-type transistor, which will not be limited to the examples illustrated herein.

The operation processes of the first thin film transistor, the first control line, and the first control circuit in the above-described touch panel provided by the embodiment of the present disclosure will be described in detail below based on the example in which each of the first thin film transistors is an N-type transistor. During the touch period, the first control circuit may apply a high level signal to each of the first control lines to control each of the first thin film transistors to be in a turned-on state, so that each of the self-capacitance electrodes is electrically connected to a corresponding connection line. During the display period, the first control circuit may load a low level signal to the first control lines to control each of the first thin film transistors to be in a turned-off state, so that each of the self-capacitance electrodes is disconnected from the corresponding connection line.

Upon implementation, as shown in FIG. 2, the touch panel provided by the embodiment of the present disclosure may further comprise a plurality of pixel units 8 on the substrate arranged in a matrix. The first control line 52 may be disposed in the gap between two adjacent rows of pixel units 8, i.e., the first control line 52 is located within the light-shielding area where the gate lines 1 reside. In this way, the first control line 52 can be prevented from interfering with other light-transmitting areas of the touch panel when it is made from an opaque metal material.

In an embodiment, the first control line may be disposed in the same layer as the gate line, i.e., the first control line and the gate line may be made of the same material in the same layer, which can simplify the manufacturing process of the touch panel and reduce the production cost thereof.

In an embodiment, as shown in FIG. 2, each pixel unit 8 may comprise a fourth thin film transistor 81 and a pixel electrode 82. The first thin film transistor 51 may be disposed in the same layer as the fourth thin film transistor 81, i.e., the gate of the thin film transistor 51 is disposed in the same layer as the gate of the fourth thin film transistor 81, the active layer of the first thin film transistor 51 is disposed in the same layer as the active layer of the fourth thin film transistor 81, and the source/drain of the first thin film transistor 51 is disposed in the same layer as the source/drain of the fourth thin film transistor 81, which can simplify the manufacturing process of the touch panel and reduce the production cost thereof.

Upon implementation, in the touch panel provided by the embodiment of the present disclosure, the second control component 6 may comprise, as shown in FIG. 2, a plurality of second thin film transistors 61 in one-to-one correspondence with the data lines 2 multiplexed as connection lines, a plurality of third thin film transistors 62 in one-to-one correspondence with the data lines 2, a second control line 63 electrically connected to each of the second thin film transistors 61, a second control circuit 64 electrically connected to the second control line 63, a third control line 65 electrically connected to each of the third thin film transistors 62, and a third control circuit 66 electrically connected to the third control line 65. Each of the second thin film transistors 61 is used to connect or disconnect the corresponding data line 2 multiplexed as a connection line with or from the touch detection chip 4, the gate of each of the second thin film transistors 61 is electrically connected to the second control line 63, the source of each of the second thin film transistors 61 may be electrically connected to the touch detection chip 4, and the drain of each of the second thin film transistors 61 may be electrically connected to the corresponding data line 2 multiplexed as a connection line. Each of the third thin film transistors 62 is used to connect or disconnect each of the data lines 2 with or from the data driving circuit 7, the gate of each of the third thin film transistors 62 is electrically connected to the third control line 65, the source of each of the third thin film transistors 62 may be electrically connected to the data driving circuit 7, and the drain of each of the third thin film transistors 62 may be electrically connected to the corresponding data line 2.

Upon implementation, in the touch panel provided by the embodiment of the present disclosure, each of the second thin film transistors may be an N-type transistor, or each of the second thin film transistors may be a P-type transistor. Moreover, each of the third thin film transistors may be an N-type transistor or a P-type transistor, which would not limit the invention herein.

The operation processes of the second thin film transistor, the second control line, the second control circuit, the third thin film transistor, the third control line and the third control circuit in the touch panel provided by the embodiment of the present disclosure will be described in detail below based on the example that each of the second thin film transistors is an N-type transistor and each of the third thin film transistors is a P-type transistor. During the touch period, the third control circuit may apply a high level signal to the third control lines to control each of the third thin film transistors to be in a turned-off state so that each of the data lines is disconnected from the data driving circuit. Moreover, the second control circuit may load a high level signal to the second control lines to control each of the second thin film transistors to be in a turned-on state, so that each of the connection lines is electrically connected to the touch detection chip. The touch detection chip loads a touch signal to corresponding self-capacitance electrodes via the connection lines, and determines a touch position by detecting a change in the capacitance value of each of the self-capacitance electrodes. During the display period, the second control circuit may load a low level signal to the second control lines to control each of the second thin film transistors to be in a turned-off state, so that each of the connection lines is disconnected from the touch detection chip, and the third control circuit may load a low level signal the third control lines to control each of the third thin film transistors to be in a turned-on state, so that each of the data lines is electrically connected to the data driving circuit. When a gate scanning signal is loaded to the respective gate lines, the data driving circuit loads a grayscale signal to the data lines to display an image.

For the touch panel provided by the embodiment of the present disclosure, in the case where the number of self-capacitance electrodes in each column of self-capacitance electrodes is smaller than the number of data lines with which this column of self-capacitance electrodes overlaps, and part of the data lines are multiplexed as connection lines, the plurality of third thin film transistors 62 may be in one-to-one correspondence with the data lines multiplexed as connection lines, for connecting or disconnecting the corresponding data lines multiplexed as connection lines with or from the data driving circuit, the gate of each of the third thin film transistors may be electrically connected to the third control line, the source of each of the third thin film transistors may be electrically connected to the data driving circuit, and the drain of each of the third thin film transistors may be electrically connected to a corresponding data line multiplexed as a connection line. During the touch period, the third control circuit controls the third thin film transistor to be in a turned-off state by means of the third control line to disconnect the connection lines from the data driving circuit, while the data lines which are not multiplexed as connection lines can still be electrically connected to the data driving circuit. Therefore, in order to prevent the data driving circuit from interfering with the touch signal by loading a grayscale signal to the data lines which are not multiplexed as connection lines, it is possible to enable the gate driving circuit to control the fourth thin film transistors to be in a turned-off state by means of the gate lines.

In an embodiment, as shown in FIG. 2, the second thin film transistor 61, the second control line 63, the second control circuit 64, the third thin film transistor 62, the third control line 65, and the third control circuit 66 may be disposed within a frame area of the touch panel that surrounds the display area. Alternatively, the second thin film transistor, the second control line and the second control circuit may also be integrated in the touch detection chip, and the third thin film transistor, the third control line and the third control circuit is may be integrated in the data driving circuit.

In an embodiment, the second control line may be disposed in the same layer as the gate line, i.e., the second control line and the gate line may be made of the same material in the same layer, which can simplify the manufacturing process of the touch panel and reduce the production cost thereof.

In an embodiment, as shown in FIG. 2, the touch panel provided by the embodiment of the present disclosure may further comprise a plurality of pixel units 8 located on the substrate and arranged in a matrix. Each of the pixel units 8 may comprise a fourth thin film transistor 81 and a pixel electrode 82. The second thin film transistor 61 may be disposed in the same layer as the fourth thin film transistor 81, i.e., the gate of the second thin film transistor 61 is disposed in the same layer as the gate of the fourth thin film transistor 81, the active layer of the second thin film transistor 61 is disposed in the same layer as the active layer of the fourth thin film transistor 81, and the source/drain of the second thin film transistor 61 is disposed in the same layer as the source/drain of the fourth thin film transistor 81, which can simplify the manufacturing process of the touch panel and reduce the production cost thereof.

In a further embodiment, the third control line may be disposed in the same layer as the gate line, i.e., the third control line and the gate line are made of the same material in the same layer, which simplify the manufacturing process of the touch panel and reduce the production cost thereof.

In the embodiment, as shown in FIG. 2, the touch panel may further comprise a plurality of pixel units 8 located on the substrate and arranged in a matrix. Each of the pixel units 8 may comprise a fourth thin film transistor 81 and a pixel electrode 82. The third thin film transistor 62 may be disposed in the same layer as the fourth thin film transistor 81, i.e., the gate of the third thin film transistor 62 is disposed in the same manner as the gate of the fourth thin film transistor 81, the active layer of the third thin film transistor 62 is disposed in the same layer as the active layer of the fourth thin film transistor 81, and the source/drain of the third thin film transistor 62 is disposed in the same layer as the source/drain of the fourth thin film transistor 81, which can simplify the manufacturing process of the touch panel and reduce the production cost thereof.

Further, for the touch panel provided by the preceding embodiments of the present disclosure, regardless of the touch period or the display period, the state of the first thin film transistor is identical with that of the second thin film transistor, and the state of the first thin film transistor is opposite to that of the third thin film transistor. Accordingly, the type of the first thin film transistor may be selected to be the same as that of the second thin film transistor, and the type of the first thin film transistor may be selected to be opposite to that of the third thin film transistor. In this way, the first control circuit, the second control circuit, and the third control circuit may be designed as the same control circuit, which may load the same electric signal to the first thin film transistor, the second thin film transistor, and the third thin film transistor simultaneously, so as to control the first thin film transistor and the second thin film transistor to be in a turned-on state while controlling the third thin film transistor to be in a turned-off state during the touch period, and control the first thin film transistor and the second thin film transistor to be in a turned-off state while controlling the third thin film transistor to be in a turned-on state during the display period, thereby simplifying the structure of the touch panel and the manufacturing process thereof, and reducing the production cost thereof.

The operation process of the touch panel will be described in detail below based on the example that the first thin film transistor and the second thin film transistor are N-type transistors and the third thin film transistor is a P-type transistor. During the touch period, the first control circuit may load a high level signal to the first thin film transistors to control each of the first thin film transistors to be in a turned-on state, so that each of the self-capacitance electrodes is electrically connected to a corresponding connection line. The third control circuit may load a high level signal to the third control lines to control each of the third thin film transistors to be in a turned-off state so that the data line is disconnected from the data driving circuit, and the second control circuit may load a high level signal to the second control lines to control each of the second thin film transistors to be in a turned-on state, so that each of the connection lines is electrically connected to the touch detection chip. The touch detection chip loads a touch scanning signal to the corresponding self-capacitance electrodes via the connection lines, and determines a touch position by detecting a change in the capacitance value of each of the self-capacitance electrodes. During the display period, the first control circuit may load a low level signal to the first control lines to control each of the first thin film transistors to be in a turned-off state so that each of the self-capacitance electrodes is disconnected from a corresponding connection line, the second control circuit may load a low level signal to the second control lines to control each of the second thin film transistors to be in a turned-off state so that each of the connection lines is disconnected from the touch detection chip, and the third control circuit may load a low level signal to the third control lines to control each of the third thin film transistors to be in a turned-on state, so that each of the data lines is electrically connected to the data driving circuit. When a gate scanning signal is loaded to the respective gate lines, the data driving circuit loads a grayscale signal to the respective data lines to display an image.

Upon implementation, in the touch panel provided by the embodiment of the present disclosure, a self-capacitance electrode may be disposed specifically on the substrate. For the touch panel provided by the embodiments of the present disclosure, the self-capacitance electrode may be an electrode disposed individually or specifically on the substrate. In a further embodiment, the common electrode layer on the substrate may be divided into a plurality of common electrodes arranged in a matrix, and the common electrode may be multiplexed as a self-capacitance electrode, so that it is not necessary to additionally arrange a self-capacitance electrode, which can simplify the manufacturing process of the touch panel, and reduce the overall thickness and the production cost thereof.

On the basis of the same inventive concept, another embodiment of the present disclosure further provides a display device comprising the in-cell touch panel provided by any one of the preceding embodiments of the present disclosure. The display device may be any product or component having display function such as a mobile phone, a tablet computer, a television, a display, a notebook computer, a digital photo frame, a navigator, and the like. Embodiments of the display device may refer to the preceding embodiments of the in-cell touch panel, repeated parts of which are not described here for simplicity.

For the in-cell touch panel and the display device provided by embodiments of the present disclosure, the data line is multiplexed as a connection line for electrically connecting the self-capacitance electrode to the touch detection chip. During the display period, the first control component is used to control each of the self-capacitance electrodes to be disconnected from a corresponding connection line, and the second control component is used to control each of the data lines to be electrically connected to the data driving circuit. During the touch period, the first control component is used to control each of the self-capacitance electrodes to be connected to a corresponding connection line, and the second control component is used to control the data lines multiplexed as connection lines to be electrically connected to the touch detection chip. In this way, a self-capacitance touch can be realized without disposing connection lines specifically in the light-shielding area where the data lines reside, which can thereby increase the aperture ratio of the self-capacitance touch panel. As a result, in the case of achieving the same brightness as the displayed image by the existing touch panel, the intensity of the backlight can be decreased, and the power consumption of the touch panel can be further reduced.

Obviously, those skilled in the art can make various modifications and variations to the present disclosure without departing from the spirit and scope of the invention. Thus, if these modifications and variations to the present disclosure pertain to the scope of the claims and equivalent technologies thereof, the present invention intends to encompass these modifications and variations.

1. An in-cell touch panel, comprising:
a substrate,
a gate line and a data line on the substrate, which are arranged in an intersecting and insulating manner,
a plurality of self-capacitance electrodes on the substrate, which are insulated from the gate line and the data line and arranged in a matrix, and
a touch detection chip for determining a touch position by detecting a change in a capacitance value of each self-capacitance electrode during a touch period,
wherein each column of self-capacitance electrodes overlaps a plurality of data lines, the number of self-capacitance electrodes included in each column of self-capacitance electrodes is smaller than or equal to the number of data lines with which each column of self-capacitance electrodes overlaps,
wherein the data line is multiplexed as a connection line for electrically connecting the self-capacitance electrode to the touch detection chip, each self-capacitance electrode is corresponding to one connection line,
wherein the touch panel further comprises a first control component and a second control component, the first control component being used for controlling each of the self-capacitance electrodes to be disconnected from a corresponding connection line during a display period, and controlling each of the self-capacitance electrodes to be electrically connected to a corresponding connection line during the touch period, the second control component being used for controlling each data line to be electrically connected to a data driving circuit during the display period, and controlling the data line multiplexed as the connection line to be electrically connected to the touch detection chip during the touch period.

2. The touch panel according to claim 1, wherein the first control component comprises: a plurality of first thin film transistors which are insulated from the gate lines and in one-to-one correspondence with the self-capacitance electrodes, a plurality of first control lines which are insulated from the gate lines and the data lines and in one-to-one correspondence with respective rows of self-capacitance electrodes, and a first control circuit electrically connected to each of the first control lines,
wherein a gate of each of the first thin film transistors to which each row of self-capacitance electrodes corresponds is electrically connected to a first control line to which each row of self-capacitance electrodes corresponds, a source of each of the first thin film transistors is electrically connected to a corresponding self-capacitance electrode, a drain of each of the first thin film transistors is electrically connected to a corresponding connection line.

3. The touch panel according to claim 2, wherein the second control component comprises: a plurality of second thin film transistors in one-to-one correspondence with the data lines multiplexed as the connection lines, a plurality of third thin film transistors in one-to-one correspondence with the data lines, a second control line electrically connected to the second thin film transistor, a second control circuit electrically connected to the second control line, a third control line electrically connected to the third thin film transistor, and a third control circuit electrically connected to the third control line,
wherein each of the second thin film transistors is used for connecting or disconnecting corresponding data lines multiplexed as the connection lines with the touch detection chip, a gate of each of the second thin film transistors is electrically connected to the second control line, a source of each of the second thin film transistors is electrically connected to the touch detection chip, a drain of each of the second thin film transistors is electrically connected to a corresponding data line multiplexed as the connection line,
wherein each of the third thin film transistors is used for connecting or disconnecting each data line with the data driving circuit, a gate of each of the third thin film transistors is electrically connected to the third control line, a source of each of the third thin film transistors is electrically connected to the data driving circuit, a drain of each of the third thin film transistors is electrically connected to a corresponding data line.

4. The touch panel according to claim 3, wherein the touch panel further comprises a plurality of pixel units located on the substrate and arranged in a matrix, the first control line is located at a gap between two adjacent rows of pixel units.

5. The touch panel according to claim 4, wherein the first control line is disposed in a same layer as the gate line.

6. The touch panel according to claim 4, wherein each of the pixel units comprises a fourth thin film transistor and a pixel electrode, the first thin film transistor is disposed in a same layer as the fourth thin film transistor.

7. The touch panel according to claim 3, wherein the second control line is disposed in a same layer as the gate line.

8. The touch panel according to claim 3, wherein the touch panel further comprises a plurality of pixel units located on the substrate and arranged in a matrix, each of the pixel units comprises a fourth thin film transistor and a pixel electrode, the second thin film transistor is disposed in a same layer as the fourth thin film transistor.

9. The touch panel according to claim 3, wherein the third control line is disposed in a same layer as the gate line.

10. The touch panel according to claim 3, wherein the touch panel further comprises a plurality of pixel units located on the substrate and arranged in a matrix, each of the pixel units comprises a fourth thin film transistor and a pixel electrode, the third thin film transistor is disposed in a same layer as the fourth thin film transistor.

11. The touch panel according to claim 3, wherein a type of the first thin film transistor is the same as that of the second thin film transistor, a type of the first thin film transistor is complementary to that of the third thin film transistor, wherein the first control circuit, the second control circuit, and the third control circuit are the same control circuit.

12. The touch panel according to any one of claim 1, wherein the self-capacitance electrodes are formed by dividing a common electrode layer on the substrate.

13. A display device comprising: an in-cell touch panel, the in-cell touch panel, comprising:
a substrate,
a gate line and a data line on the substrate, which are arranged in an intersecting and insulating manner,
a plurality of self-capacitance electrodes on the substrate, which are insulated from the gate line and the data line and arranged in a matrix, and
a touch detection chip for determining a touch position by detecting a change in a capacitance value of each self-capacitance electrode during a touch period,
wherein each column of self-capacitance electrodes overlaps a plurality of data lines, the number of self-capacitance electrodes included in each column of self-capacitance electrodes is smaller than or equal to the number of data lines with which each column of self-capacitance electrodes overlap,
wherein the data line is multiplexed as a connection line for electrically connecting the self-capacitance electrode to the touch detection chip, each self-capacitance electrode is corresponding to one connection line,
wherein the touch panel further comprises a first control component and a second control component, the first control component being used for controlling each of the self-capacitance electrodes to be disconnected from a corresponding connection line during a display period, and controlling each of the self-capacitance electrodes to be electrically connected to a corresponding connection line during the touch period, the second control component being used for controlling each data line to be electrically connected to a data driving circuit during the display period, and controlling the data line multiplexed as the connection line to be electrically connected to the touch detection chip during the touch period.

14. The display device according to claim 13, wherein the first control component comprises: a plurality of first thin film transistors which are insulated from the gate lines and in one-to-one correspondence with the self-capacitance electrodes, a plurality of first control lines which are insulated from the gate lines and the data lines and in one-to-one correspondence with respective rows of self-capacitance electrodes, and a first control circuit electrically connected to each of the first control lines,
wherein a gate of each of the first thin film transistors to which each row of self-capacitance electrodes corresponds is electrically connected to a first control line to which each row of self-capacitance electrodes corresponds, a source of each of the first thin film transistors is electrically connected to a corresponding self-capacitance electrode, a drain of each of the first thin film transistors is electrically connected to a corresponding connection line.

15. The display device according to claim 14, wherein the second control component comprises: a plurality of second thin film transistors in one-to-one correspondence with the data lines multiplexed as the connection lines, a plurality of third thin film transistors in one-to-one correspondence with the data lines, a second control line electrically connected to the second thin film transistor, a second control circuit electrically connected to the second control line, a third control line electrically connected to the third thin film transistor, and a third control circuit electrically connected to the third control line,
wherein each of the second thin film transistors is used for connecting or disconnecting corresponding data lines multiplexed as the connection lines with the touch detection chip, a gate of each of the second thin film transistors is electrically connected to the second control line, a source of each of the second thin film transistors is electrically connected to the touch detection chip, a drain of each of the second thin film transistors is electrically connected to a corresponding data line multiplexed as the connection line,
wherein each of the third thin film transistors is used for connecting or disconnecting each data line with the data driving circuit, a gate of each of the third thin film transistors is electrically connected to the third control line, a source of each of the third thin film transistors is electrically connected to the data driving circuit, a drain of each of the third thin film transistors is electrically connected to a corresponding data line.

16. The display device according to claim 15, wherein the touch panel further comprises a plurality of pixel units located on the substrate and arranged in a matrix, the first control line is located at a gap between two adjacent rows of pixel units.

17. The display device according to claim 16, wherein the first control line is disposed in a same layer as the gate line.

18. The display device according to claim 16, wherein each of the pixel units comprises a fourth thin film transistor and a pixel electrode, the first thin film transistor is disposed in a same layer as the fourth thin film transistor.

19. The display device according to claim 15, wherein the second control line is disposed in a same layer as the gate line.

20. The display device according to claim 15, wherein the touch panel further comprises a plurality of pixel units located on the substrate and arranged in a matrix, each of the pixel units comprises a fourth thin film transistor and a pixel electrode, the second thin film transistor is disposed in a same layer as the fourth thin film transistor.
